(19) United States
(12) Patent Application Publication
(10) Pub. No.: US 2008/0042774 A1
(43) Pub. Date: Feb. 21, 2008

(54) Broadband impedance matching circuit using high pass and low pass filter sections

(75) Inventor: Robert D. Talbot, Pittsford, NY (US)

Correspondence Address: HOLLAND & KNIGHT LLP;ATTN: STEFAN V. STEIN/ IP DEPT., POST OFFICE BOX 1288, TAMPA, FL, 33601-1288, US

(73) Assignee: Harris Corporation

(21) Appl. No.: 11/507,409

(22) Filed: Aug. 21, 2006

(51) Int. Cl. H03H 7/38

(52) U.S. Cl. 333/33

(57) ABSTRACT

A broadband impedance matching circuit using high pass and low pass filter sections alternatingly cascaded together to yield considerably broader band matching than two high pass sections or two low pass filter sections. By alternating the high pass filter sections with the low pass filter sections, significantly fewer elements are required for a given result than non-alternating prior art cascaded filter sections. Consequently, the alternating filter sections according to the present invention significantly improves the return loss at increased bandwidths.

### STATEMENT REGARDING FEDERALLY SPONSORED RESEARCH OR DEVELOPMENT

The United States Government has certain rights in and to this invention pursuant to Government Contract No. FA8709-04C-0010.

### BACKGROUND OF THE INVENTION

1. Field of the Invention

This invention relates to impedance matching. More particularly, this invention relates to broadband impedance matching employing high pass and low pass filters.

2. Description of the Background Art

The maximum transfer of power from a source to its load occurs when the load impedance is equal to the complex conjugate of the source impedance. More specifically, when the load impedance is equal to the complex conjugate of the source impedance, any source reactance is resonated with an equal but opposite load reactance, leaving only equal resistive values for the source and load impedances. Maximum power is thus transferred from the source to the load because the source resistance equals the load resistance.

The simplest matching circuit for matching two real impedances is a network composed of two elements—an inductor and a capacitor—connected in an “L” network. When the shunt element is the capacitor, the L network functions as a low pass filter because low frequencies flow through the series inductor whereas high frequencies are shunted to ground. When the shunt element is the inductor, the L network functions as a high pass filter because high frequencies flow through the capacitor whereas low frequencies are shunted to ground. Impedance matching is attained because the shunt element transforms a larger impedance down to a smaller value with a real part equal to the real part of the other terminating impedance. The series element then resonates with or cancels any reactive components, thus leaving the source driving an apparently equal load for optimum power transfer.

Simple L networks may also be used for matching two complex impedances containing both resistive and capacitive reactive components, such as transmission lines, mixers and antennas. One approach for matching complex impedances includes absorbing any stray reactances into the impedance matching network itself. Absorption is typically accomplished by capacitor elements placed in parallel with stray capacitances and inductor elements placed in series with any stray inductances.

Three element matching networks are commonly known as the Pi network and the T network, each comprising two back-to-back L networks cascaded together to provide a multi-section of low or high pass matching network for matching two complex impedances. Pi and T networks offer an advantage over L networks of being able to select a circuit Q independent of the source and load impedances as long as the Q chosen is larger than that which is available with the L network. Unfortunately, however, Pi and T networks are narrow-banded and therefore not suitable for broadband impedance matching. Further, Pi and T networks employ many components for a given design criteria.

Unlike back-to-back L networks in the form of a Pi or T network, series-connected L networks offer increased bandwidth. An even wider bandwidth may be achieved by cascading additional L networks with virtual resistances between each network. For example, FIG. 1 is a schematic diagram of three networks cascaded with virtual resistances between each network. Optimum bandwidth is obtained when the ratios of each of the two succeeding resistances are equal: R1/Rₛₘₐₗₗₑᵣ=R₂/R₁=R₃/R₂ . . . =R_{larger}/Rₙ, where Rₛₘₐₗₗₑᵣ=the smallest terminating resistance, R_{larger}=the largest terminating resistance, and R₁, R₂, . . . Rₙ=virtual resistors that are equal to the geometric mean of the two impedances being matched (i.e., R=√(R_{S}R_{L})). Computer programs using ADS facilitate the selection of network elements for particular insertion loss, bandwidth and return loss.

Presently, there exist many variations of impedance-matching cascaded L and other networks that achieve broader bandwidths. For example, U.S. Pat. No. 4,003,005, the disclosure of which is hereby incorporated by reference herein, discloses two L networks cascaded back-to-back in the form of low pass filters with a symmetrical all-pass network interposed therebetween which provides isolation between low pass filter sections thereby providing a constant input/output impedance to remove the impedance variation caused by the filters. A similar embodiment employing high pass filters is also disclosed. U.S. Pat. No. 4,612,571, the disclosure of which is hereby incorporated by reference herein, discloses a low pass filter, a high pass filter and a bandpass filter configured to provide a flat input impedance. Finally, U.S. Pat. No. 6,608,536, the disclosure of which is hereby incorporated by reference herein, discloses a constant impedance filter in the form of a low pass filter, a high pass filter or a bandpass filter that maintains a constant input impedance for frequencies that are both inside the filter passband and outside the filter passband.

Unfortunately, the aforementioned prior art impedance matching circuits are complex in design and require many elements that appreciably increases the return loss reflection.

Therefore, it is an object of this invention to provide an improvement which overcomes the aforementioned inadequacies of the prior art devices and provides an improvement which is a significant contribution to the advancement of the broadband impedance-matching art.

Another object of this invention is to provide a broadband impedance matching circuit utilizing high pass and low pass filter sections alternatingly cascaded together to minimize the number of elements required while achieving an improved return loss across a broad band of frequencies up to about 2 GHz or more.

The foregoing has outlined some of the pertinent objects of the invention. These objects should be construed to be merely illustrative of some of the more prominent features and applications of the intended invention. Many other beneficial results can be attained by applying the disclosed invention in a different manner or modifying the invention within the scope of the disclosure. Accordingly, other objects and a fuller understanding of the invention may be had by referring to the summary of the invention and the detailed description of the preferred embodiment in addition to the scope of the invention defined by the claims taken in conjunction with the accompanying drawings.

### SUMMARY OF THE INVENTION

For the purpose of summarizing the invention, the invention comprises a broadband impedance matching circuit using high pass and low pass filter sections alternatingly cascaded together to match different impedances across a frequency range such as 50 ohms to 25 ohms in a variety of applications such a matching 50 ohms to the load impedance needed by a RF power amplifier to produce the required output. If the first element of the circuit is a shunt element and the impedances are resistive, then the circuit transforms from a high to low impedance whereas if the first element of the circuit is a series element, then the transformation will be from a low to a higher impedance.

More particularly, a high pass filter section followed by a low pass filter section yield considerably broader band matching than two high pass sections or two low pass filter sections. Moreover, by alternating the high pass filter sections with the low pass filter sections, significantly fewer elements are required for a given result than non-alternating prior art cascaded filter sections. Consequently, the alternating filter sections according to the present invention significantly improves the return loss at increased bandwidths.

The foregoing has outlined rather broadly the more pertinent and important features of the present invention in order that the detailed description of the invention that follows may be better understood so that the present contribution to the art can be more fully appreciated. Additional features of the invention will be described hereinafter which form the subject of the claims of the invention. It should be appreciated by those skilled in the art that the conception and the specific embodiment disclosed may be readily utilized as a basis for modifying or designing other circuits and assemblies for carrying out the same purposes of the present invention. It should also be realized by those skilled in the art that such equivalent circuits and assemblies do not depart from the spirit and scope of the invention as set forth in the appended claims.

### BRIEF DESCRIPTION OF THE DRAWINGS

For a fuller understanding of the nature and objects of the invention, reference should be had to the following detailed description of the preferred embodiment taken in connection with the accompanying drawings in which:

FIG. 1 is a schematic diagram of a prior art impedance matching circuit composed of cascaded L networks; and

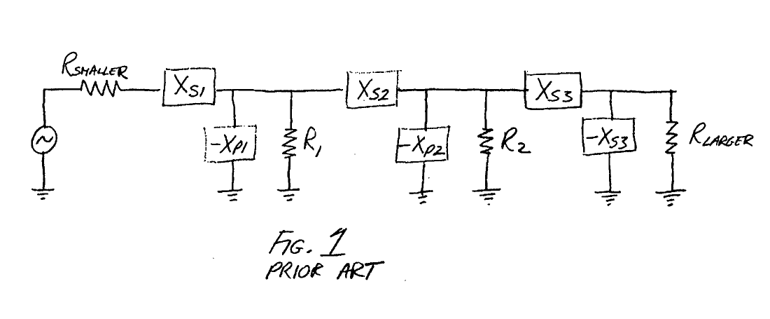

FIGS. 2A and 2B are block diagrams of the broadband impedance matching circuit composed of alternating low pass and high pass filters according to the present invention.

Similar reference characters refer to similar parts throughout the several views of the drawings.

### DETAILED DESCRIPTION OF THE PREFERRED EMBODIMENT

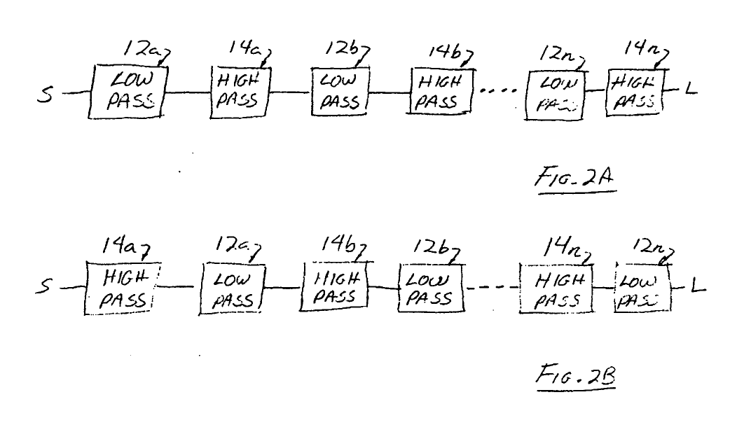

Referring to FIG. 2, the preferred embodiment of the broadband impedance matching circuit 10 comprises a plurality of low pass filters 12 and a plurality of high pass filters 14 alternatingly cascaded together between a source S whose impedance is to be matched to the impedance of a load L. The alternating cascaded sequence may begin or end with a low pass filter or a high pass filter (FIG. 2A shows the sequence beginning with a low pass section followed by a high pass section whereas FIG. 2B shows the sequence beginning with a high pass section followed by a low pass section).

More particularly, in FIG. 2A the output of the first low pass filter 12a is connected to the input of the first high pass filter 12b. Then, the output of the first high pass filter 12a is connected to the input of the second low pass filter 12b whose output is connected to the input of the second high pass filter 14b. Likewise, the output of the second high pass filter 14b is connected to the input of the third low pass filter 12c whose output is connected to the input of the third high pass filter 14c. This alternating sequence repeats itself for each pair of low pass filters 12_{N} and high pass filters 14_{N}.

In FIG. 2B, the output of the first high pass filter 14a is connected to the input of the first low pass filter 12a. Then, the output of the first low pass filter 12a is connected to the input of the second high pass filter 14b whose output is connected to the input of the second low pass filter 12b. Likewise, the output of the second low pass filter 12b is connected to the input of the third high pass filter 14c whose output is connected to the input of the third low pass filter 12c. This alternating sequence repeats itself for each pair of high pass filters 12_{N} and low pass filters 14_{N}.

The low pass filters 12 and the high pass filters 14 preferably comprise network topologies that minimize the number of elements that are required for each. Such minimization may result from simple network topologies having fewer elements in the first instance and/or network topologies that share elements with adjacent networks.

For the purposes of illustration and not limitation, for an eight element circuit 10 that matches 50 ohms to 25 ohms from 0.2 GHz to 2 GHZ with a return loss of greater than 20 dB, the low pass filters 12 and the high pass filters 14 may comprise the following eight elements:

C1shunt-1.42 pfs

L1series-4.99nh

L2shunt-36.28nh

C2series-14.44pfs

C3shunt-3.39pfs

L3series-2.35nh

L4shunt-16.11nh

C4series-32.82pfs

Without departing from the spirit and scope of the invention the source S and load L may comprises a variety of devices such as transmission lines, mixers and antennas. Moreover, due to its wide bandwidth, the matching network of the invention is particularly suited for combining several stages in a power amplifier.

The present disclosure includes that contained in the appended claims, as well as that of the foregoing description. Although this invention has been described in its preferred form with a certain degree of particularity, it is understood that the present disclosure of the preferred form has been made only by way of example and that numerous changes in the details of construction and the combination and arrangement of parts may be resorted to without departing from the spirit and scope of the invention.

Now that the invention has been described,

What is claimed is:

1. A broadband impedance matching circuit, comprising in combination:
a plurality of low pass filters;
a plurality of high pass filters;
said low pass filters and said high pass filters being serially connected by an alternatingly cascaded sequence between a source whose impedance is to be matched to the impedance of a load.

2. The broadband impedance matching circuit as set forth in claim 1, wherein said alternatingly cascaded sequence comprises connecting an output of a first low pass filter to an input of a first high pass filter, wherein an output of the first high pass filter is connected to an input of a second low pass filter whose output is connected to an the input of a second high pass filter, and wherein an output of the second high pass filter is connected to an input of a third low pass filter whose output is connected to an input of a third high pass filter.

3. The broadband impedance matching circuit as set forth in claim 2, wherein alternatingly cascaded sequence is repeated for a N number of sequences.

4. The broadband impedance matching circuit as set forth in claim 1, wherein said alternatingly cascaded sequence comprises connecting an output of a first high pass filter to an input of a first low pass filter, wherein an output of the first low pass filter is connected to an input of a second high pass filter whose output is connected to an the input of a second low pass filter, and wherein an output of the second low pass filter is connected to an input of a third high pass filter whose output is connected to an input of a third low pass filter.

5. The broadband impedance matching circuit as set forth in claim 4, wherein alternatingly cascaded sequence is repeated for a N number of sequences.
